(19) United States
(12) Patent Application Publication
(10) Pub. No.: US 2005/0224816 A1
(43) Pub. Date: Oct. 13, 2005

(54) Nitride based semiconductor having improved external quantum efficiency and fabrication method thereof

(76) Inventors: Sun Woon Kim, Seoul (KR); Jeong Tak Oh, Suwon (KR); Kyu Han Lee, Suwon (KR); Je Won Kim, Suwon (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/873,239

(22) Filed: Jun. 23, 2004

(30) Foreign Application Priority Data
Mar. 30, 2004 (KR) 2004-21802

(51) Int. Cl. H01L 27/15

(52) U.S. Cl. 257/79

(57) ABSTRACT

A surface treated nitride semiconductor in use for a light emitting diode, in which an n-cladding layer is formed on a substrate. An active layer having a multiple quantum well structure is formed on the n-cladding layer. A p-cladding layer is formed on the active layer. A p-capping layer is formed on the p-cladding layer in a low temperature range in which single crystal growth does not take place. The p-capping layer has a nanoscale roughened structure formed in an upper surface thereof via heat treatment in a high temperature range in which at least partial crystallization takes place. The nanoscale roughened structure reduces total internal reflection of the nitride semiconductor thereby improving external quantum efficiency thereof.

### CLAIM OF PRIORITY

This application claims the benefit of Korean Patent Application No. 2004-21802 filedonMar. 30, 2004, in the Korean Intellectual Property Office, the disclosure of which is incorporated herein by reference.

### BACKGROUND OF THE INVENTION

1. Field of the Invention

The present invention relates to a nitride semiconductor in use for an optoelectronic device, and more particularly, to a nitride semiconductor having a nanoscale roughened structure in an upper region of a p-capping layer formed through high temperature heat treatment to reduce total internal reflection thereby improving external quantum efficiency and a fabrication method thereof.

2. Description of the Related Art

In general, a nitride-based or nitride semiconductor for example of InAlGaN is used in a Light Emitting Doide (LED) for producing blue or green wavelength light. The nitride semiconductor has a representative formula of AlₓIn_{y}Ga_{(1-x-y)}N, in which 0≦x≦1, 0≦y≦1 and 0≦x+y≦1. The nitride semiconductor is fabricated by growing nitride epitaxial layers including an n-cladding layer, an active layer and a p-cladding layer on a substrate of for example sapphire via the Metal Organic Chemical Vapor Deposition (MOCVD).

The light emitting efficiency of an LED is determined by an internal quantum efficiency indicating light quantity generated from inside the LED with respect to an external voltage and an external quantum efficiency measured outside the LED with respect to the external voltage. In this case, the external quantum efficiency is expressed as multiplication of the internal quantum efficiency by an extraction efficiency. Therefore, in order to improve the light emitting efficiency of an LED, it is essential to raise not only the internal quantum efficiency but also the external quantum efficiency. The internal quantum efficiency is generally determined by the structure of an active layer and the film quality of an epitaxial layer, and the external quantum efficiency is determined by the refractive index of a semiconductor material and the surface flatness thereof.

Nitride semiconductors have a refractive index typically in the range from about 2.2 to 2.9, and LEDs formed by the growth of such nitride semiconductor materials have an external quantum efficiency merely in the range from about 10 to 20%. As a consequence, the external quantum efficiency can be improved on the basis of surface flatness in order to fabricate high efficiency LEDs. That is, the surface of an LED is roughened to reduce the angle total reflection of light escaping from the LED thereby decreasing the internal reflection of light and thus raising light extraction efficiency.

As an example of technologies for raising the light extraction efficiency as above, there was proposed U.S. Pat. No. 5,040,044 entitled “Compound Semiconductor Device and Method for Surface Treatment.” This approach is aimed to roughen the surface of an LED through chemical etching thereby to reduce the total internal reflection while raising the light extraction efficiency. However, its etching process has poor efficiency because nitride semiconductors poorly react to acidic or basic etching solution.

As another example, there was proposed U.S. Pat. No. 6,258,618 entitled “Light Emitting Device Having a Finely-Patterned Reflective Contact.” This approach was devised to raise the light extraction efficiency of nitride-based semiconductor devices. In this approach, after a p-contact metal layer is formed on a p-doped semiconductor layer, a patterning process is performed so that the p-contact metal and the p-doped semiconductor layer are etched in part thereby forming an open structure. Then, the metal layer gets to have a mesh structure for facilitating current dispersion and open areas for increasing the light extraction efficiency. However, there are drawbacks that the patterning process is to be added and it is impossible to form a pattern smaller than micrometer size.

As further another example, there was proposed U.S. Pat. No. 6,441,403 entitled “Semiconductor Device with Roughened Surface Increasing External Quantum Efficiency.” This document discloses an approach of growing a p-cladding layer in a low temperature range thereby to spontaneously form an epitaxial layer having a roughened surface. However, the p-cladding layer may have for example V defects when grown in the low temperature range owing to defects such as dislocations (e.g., threading dislocations) which are connected from an n-cladding layer to an active layer. This as a result heavily deteriorates reverse bias and electrostatic characteristics of a semiconductor device.

### SUMMARY OF THE INVENTION

The present invention has been made to solve the foregoing problems of the prior art and it is therefore an object of the present invention to provide a nitride semiconductor having a nanoscale roughened structure which is formed in an upper region of a p-capping layer via high temperature heat treatment to decrease internal reflection thereby improving external quantum efficiency.

It is another object of the invention to provide a nitride semiconductor in which a p-cladding layer underlying the high temperature grown p-capping layer is treated in a high temperature range thereby to prevent defects in the surface of an active layer from being connected to the p-capping layer.

It is further another object of the invention to provide a fabrication method of nitride semiconductors for forming a nanoscale roughened structure in an upper region of a p-capping layer via high temperature heat treatment to reduce internal reflection thereby improving external quantum efficiency.

It is yet another object of the invention to provide a fabrication method of nitride semiconductors for growing a p-cladding layer underlying a p-capping layer in a high temperature range in order to prevent defects in the surface of an active layer from being connected to the p-capping layer.

According to an aspect of the invention for realizing the object, there is provided a surface treated nitride semiconductor for a light emitting diode comprising: an n-cladding layer formed on a substrate; an active layer having a multiple quantum well structure formed on the n-cladding layer; a p-cladding layer formed on the active layer; and a p-capping layer formed on the p-cladding layer in a low temperature range in which single crystal growth does not take place, the p-capping layer having a nanoscale roughened structure formed in an upper surface thereof via heat treatment in a high temperature range in which at least partial crystallization takes place.

In the nitride semiconductor of the invention, the p-capping layer may have an amorphous or polycrystalline structure, and formed at a temperature range preferably from about 300 to 700° C. and more preferably from about 300 to 400° C.

Preferably, the nanoscale roughened structure has a number of protrusions having a diameter of about 5 to 500 nm or a number of pores having a width of about 5 to 500 nm, and is formed at a temperature range from about 700 to 1300° C.

In addition, the substrate may be one selected from a group consisting of a sapphire substrate, a SiC substrate, an oxide substrate and a carbide substrate.

According to another aspect of the invention for realizing the object, there is provided a fabrication method of surface treated nitride semiconductors for a light emitting diode, the method comprising the following steps of:
(a) forming an n-cladding layer on a substrate;
(b) forming an active layer having a multiple quantum well structure on the n-cladding layer;
(c) forming a p-cladding layer on the active layer;
(d) forming a p-capping layer on the p-cladding layer at a low temperature range in which single crystal growth does not take place; and
(e) heat treating the p-capping layer at a high temperature range, whereby the p-capping layer is at least partially crystallized to form a nanoscale roughened structure in an upper region thereof.

In the fabrication method of the invention, the step (d) of forming a p-capping layer may be carried out at a temperature range preferably from about 300 to 700° C. and more preferably from about 300 to 400° C.

In the fabrication method of the invention, the step (d) of forming a p-capping layer may be carried out at a predetermined molar ratio of III group element to V group element preferably in the range from about 10 to 5000 and more preferably about 10 to 1000.

Also, the heat treatment step (e) may be carried out in a temperature range preferably from about 700 to 1300° C., and for about 1 to 10 minutes and more preferably for about 2 to 7 minutes.

Preferably, the heat treatment step (e) may comprise feeding anti-decomposition gas at a flow rate in the range from about 2 to 10 liters per minute

Preferably, the heat treatment step (e) may comprise feeding anti-decomposition gas at a flow rate in the range from about 2 to 10 liters per minute for preventing decomposition of the p-capping layer, wherein the anti-decomposition gas is at least one selected from a group consisting of tertiarybutylamine (N(C₄H₉)H₂), phenylhydrazine (C₆H₈N₂) and dimethylhydrazine (C₂H₈N₂).

In addition, the substrate may be one selected from a group consisting of a sapphire substrate, a SiC substrate, an oxide substrate and a carbide substrate.

### BRIEF DESCRIPTION OF THE DRAWINGS

FIG. 1 is a flowchart illustrating a fabrication method of nitride semiconductors of the invention;

FIG. 2 is a process sectional view illustrating the fabrication method of nitride semiconductors of the invention, in which a p-capping layer is formed in a low temperature range;

FIG. 3 is a process sectional view illustrating the fabrication method of nitride semiconductors of the invention, in which a nanoscale roughened structure is formed in an upper region of the p-capping layer through high temperature heat treatment;

FIG. 4 is an AFM photograph of ap-capping layer of a nitride semiconductor of the prior art;

FIG. 5 is an AFM photograph of a p-capping layer of a nitride semiconductor of the invention, which is high temperature heat treated for about 2 minutes; and

FIG. 6 is an AFM photograph of a p-capping layer of a nitride semiconductor of the invention, which is high temperature heat treated for about 5 minutes.

### DETAILED DESCRIPTION OF THE PREFERRED EMBODIMENT

The above and other objects, features and other advantages of the present invention will be more clearly understood from the following detailed description taken in conjunction with the accompanying drawings, in which:

Among terminologies used for explaining a nitride semiconductor and a fabrication method thereof of the invention, the terminology “low temperature range” designates a temperature range in which a p-capping layer of the nitride semiconductor maintains an amorphous or polycrystalline structure without crystallization, but the terminology “high temperature range” designates a temperature range in which the p-capping layer is at least partially phase transformed into a specific crystal structure.

A structure of a nitride semiconductor 10 of the invention will be first described with reference to FIG. 3.

The nitride semiconductor 10 is used with an optoelectronic device such as an LED, and includes a transparent substrate 12 for example of sapphire and an n-cladding layer 14, an active layer 16, a p-cladding layer 18 and a p-capping layer 20a which are formed in their order on the sapphire substrate 12.

The n-cladding layer 14 is an epitaxial layer grown on a buffer layer (not shown) between the sapphire substrate 12 and the n-cladding layer 14 because of the lattice constant mismatch between the sapphire substrate 12 and the n-cladding layer 14. The active layer 16 for generating light is formed on the n-cladding layer 14.

The active layer 16 has a Multiple Quantum Well (MQW) structure formed by growing wells typically of InGaN and barrier layers of (Al)GaN. Blue LEDs use an MQW structure of for example InGaN/GaN, and ultraviolet (UV) LEDs use an MQW structure of for example GaN/AlGaN, InAlGaN/InAlGaN or InGaN/AlGaN. As for the efficiency improvement of active layers as above, the internal quantum efficiency ηᵢ is improved by adjusting light wavelength through variation in the content of In or Al. Alternatively, the quantum well depth, number or thickness of active layers may be changed in order to improve the internal quantum efficiency ηᵢ.

Also, the p-capping layer 20a is grown on the p-cladding layer 18 in a low temperature range in which single crystal growth does not take place, and an upper region of the p-capping layer 20a is transformed into a nanoscale roughened structure 22 through heat treatment in a high temperature region.

The p-capping layer 20a is grown into an amorphous or polycrystalline structure in the low temperature range preferably from about 300 to 700° C. and more preferably from about 300 to 400° C., and the roughened structure 22 is formed in the upper region of the p-capping layer in the high temperature region preferably from about 700 to 1300° C. That is, when the p-capping layer 20a is heat treated in the high temperature region, amorphous or polycrystalline GaN compound in the upper region of the p-capping layer 20a is at least partially transformed into crystals forming a number of nanoscale protrusions or pores thereby to obtain the nanoscale roughened structure 22.

The nanoscale roughened structure 22 increases the surface roughness of the nitride semiconductor 10 to reduce the total internal reflection thereby allowing light generated from the active layer 16 to escape more efficiently to the outside. That is, the nanoscale roughened structure 22 increases the external quantum efficiency of the nitride semiconductor 10.

The nanoscale roughened structure 22 is realized by a number of pores or protrusions (or pillars) which have a width or diameter preferably in the range from about 5 to 500 nm. Further, when interpreted in Atomic Force Microscope (AFM) photographs, this structure has a roughness preferably in the range from about 2 to 50 nm in Average Roughness (RA) or 2 to 50 nm in Root Mean Square (RMS).

The nanoscale roughened structure 22 increases the surface roughness of the nitride semiconductor 10 to improve the external quantum efficiency, resultantly elevating the quantum efficiency of an optoelectronic device such as an LED to which the nitride semiconductor 10 may be applied. Further, the high temperature treatment of the p-cladding layer 18 can prevent defects such as threading dislocation, which may exist in the underlying active layer 16, from being connected to the p-cladding layer 18. Such features of the nitride semiconductor 10 of the invention can prevent reverse bias or electrostatic characteristics deterioration originated from threading dislocation which are pointed out in afore-described U.S. Pat. No. 6,441,403.

In the meantime, the sapphire substrate 12 adopted in the nitride semiconductor 10 of the invention may be replaced by one selected from the group consisting of a silicon carbide (SiC) substrate, an oxide substrate and a carbide substrate.

In addition, because the p-capping layer 20a has excellent wettability to metal thanks to the nanoscale roughened structure 22, a transparent electrode in a subsequent process can be made of one selected from the group consisting of indium-tin oxide (ITO), cadmium-tin oxide (CTO) and tin-tungsten nitride (TiWN).

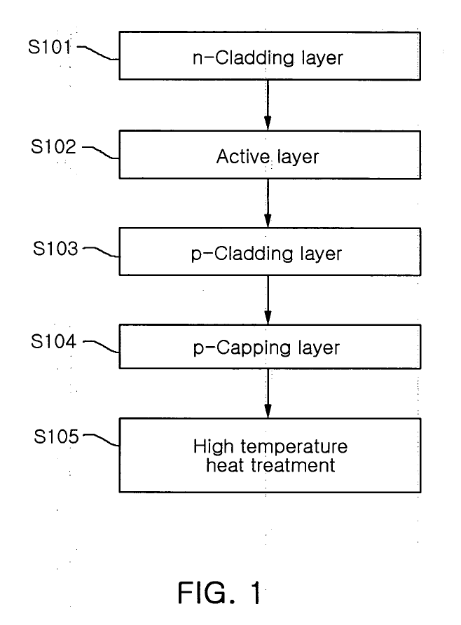

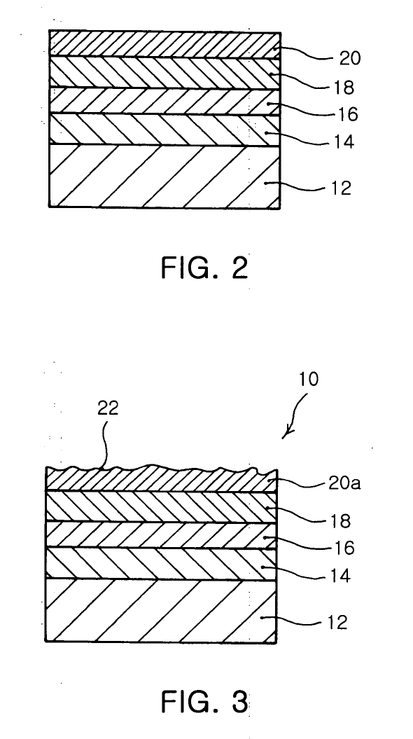

Hereinafter a fabrication method of nitride semiconductors of the invention will be described with reference to FIGS. 1 to 3, in which FIG. 1 is a flowchart illustrating the fabrication method of nitride semiconductors of the invention, FIG. 2 is a process sectional view illustrating the fabrication method of nitride semiconductors of the invention, in which a p-capping layer is formed in a low temperature range, and FIG. 3 is a process sectional view illustrating the fabrication method of nitride semiconductors of the invention, in which a nanoscale roughened structure is formed in an upper region of the p-capping layer through high temperature range heat treatment.

First, a substrate 12 for example of sapphire is loaded into an MOCVD reactor. Next the sapphire substrate 12 is heated at a predetermined temperature while trimethyl gallium (TMG) or triethyl gallium (TEG) is fed on ammonia (NH₃) gas into the MOCVD thereby to form an n-cladding layer 14 in S101. The step S101 of forming the n-cladding layer 140 will not described in detail since it can be performed according to techniques and conditions well known in the art.

Alternatively, the sapphire substrate 12 can be replaced by one selected from the group consisting of a SiC substrate, an oxide substrate and a carbide substrate.

In steps S102 and S103, an active layer 16 and a p-cladding layer 18 are formed on the n-cladding layer 14 in their order. These steps S102 and S103 also will not be described in detail since they are well known in the art.

Then, a p-capping layer 20 having an amorphous or polycrystalline structure is formed on the p-cladding layer 18 in S104. In order to avoid any crystallization originated from phase transformation, this step S104 is carried out in a low temperature range preferably from about 300 to 700° C. and more preferably from about 300 to 400° C. In this step S104, group III element for example Ga is fed in the form of TMG or TEG on NH₃ gas into the MOCVD reactor, in which the molar ratio of Ga to group V element for example nitrogen (N₂) is maintained preferably in the range from about 10 to 5000 and more preferably from about 10 to 1000.

Next, the inflow of Ga is stopped and the temperature of the MOCVD reactor is raised to a high temperature range from about 700 to 1300° C. to heat treat the p-capping layer 20 thereby forming a nitride semiconductor 10 of the invention in S105.

This heat treatment step S105 is carried out preferably for about 1 to 10 minutes and more preferably for about 2 to 7 minutes while NH₃ gas is fed preferably at a flow rate of about 2 to 10 liters per minute. Then, the surface of the p-capping layer 20a is at least partially crystallized through phase transformation into the nanoscale roughened structure 22. Further, during the heat treatment in the high temperature range, inflow NH₃ gas prevents the decomposition of the p-capping layer 20a that is at least partially phase-transformed.

Also, as a metalorganic source for preventing the deposition of the p-capping layer 20a, NH₃ gas may be used together with or replaced by at least one selected from the group consisting of tertiarybutylamine (N(C₄H₉)H₂), phenylhydrazine (C₆H₈N₂) and dimethylhydrazine (C₂H₈N₂). Alternatively, nitrogen or inactive gas may be added to the above gases in the heat treatment step S105.

The nanoscale roughened structure 22 obtained by the heat treatment step S105 is constituted of a number of pores or protrusions (or pillars) which have a width or diameter preferably in the range from about 5 to 500 nm. In addition, when interpreted in Atomic Force Microscope (AFM) photographs, this structure has a roughness preferably in the range from about 2 to 50 nm in Average Roughness (RA) or 2 to 50 nm in Root Mean Square (RMS).

When produced as above, the nitride semiconductor 10 of the invention increases the surface roughness as above to elevate the external quantum efficiency thereby improving the quantum efficiency of an optoelectronic device such as an LED to which the nitride semiconductor 10 of the invention is applied.

After being fabricated as above, the nitride semiconductor 10 of the invention may be transferred to a following process after being cooled down to a room temperature via for example quenching or annealing. That is, a transparent electrode or current electrode may be formed on the p-capping layer 20a having the nanoscale roughened structure 22. Alternatively, another semiconductor layer may be formed for another purpose.

In the meantime, the p-capping layer 20a has excellent wettability to metal owing to the nanoscale roughened structure 22, and thus can adopt one selected from the group consisting of ITO, CTO and TIWN of excellent transmittancy as a transparent electrode.

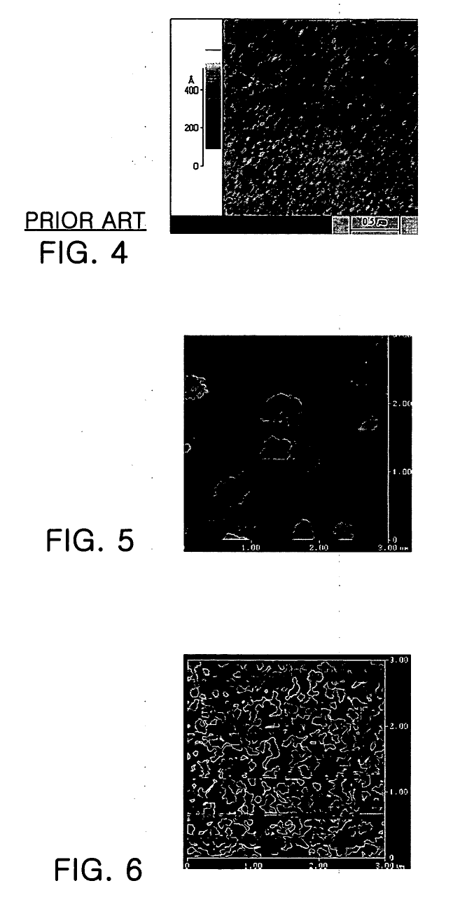

Hereinafter the surface morphology of a nitride semiconductor fabricated according to the invention will be compared with that of a conventional nitride semiconductor with reference to FIGS. 4 to 6, in which FIG. 4 is an AFM photograph of a p-capping layer of a nitride semiconductor of the prior art, FIG. 5 is an AFM photograph of a p-capping layer of a nitride semiconductor of the invention, which is high temperature heat treated for about 2 minutes, and FIG. 6 is an AFM photograph of a p-capping layer of a nitride semiconductor of the invention, which is high temperature heat treated for about 5 minutes.

Nitride semiconductors of the invention and a conventional nitride semiconductor were measured of surface roughness by AFM photographs, and results are reported in Table 1 below:

TABLE 1

| Classification | Comp. Exam. | Invent. Exam. 1 | Invent. Exam. 2 |
|---|---|---|---|
| RA | 1.8 nm | 2.52 nm | 8.16 nm |
| RMS | 2.33 nm | 3.38 nm | 9.78 nm |

In Table 1, Average Roughness (RA) indicates the height deviation of protrusions or pores formed in the surface of the nitride semiconductors, and Root Mean Square (RMS) indicates the standard deviation of the height of protrusions or pores formed in the surface of the nitride semiconductors.

Therefore, it can be seen that the conventional nitride semiconductor (i.e., Comparative Example) shown in FIG. 4 has a very smooth surface compared to the nitride semiconductors of the invention (i.e., Inventive Examples 1 and: 2) shown in FIGS. 5 and 6. That is, the nitride semiconductors of the invention have higher surface roughness and thus better external quantum efficiency than the conventional nitride semiconductor.

It is also apparent that the Inventive Example 2 (in FIG. 6) that was heat treated for 5 minutes has higher surface roughness than the Inventive Example 1 (in FIG. 5) that was heat treated for 2 minutes.

Brightness growth in the Comparative Example and the Inventive Examples 1 and 2 according to the surface roughness improvement are reported in Table 2 below:

TABLE 2

| Time | Comp. Exam. | Invent. Exam. 1 | Invent. Exam. 2 |
|---|---|---|---|
| RMS | 2.33 | 3.38 | 9.78 |
| Brightness | 0% | 3% | 8% |

As can be seen from Table 2, the high temperature heat treatment performed according to the invention increases the surface roughness of the nitride semiconductors of the Inventive Examples 1 and 2 thereby improving their brightness. As a result, the nitride semiconductors of the invention have more excellent external quantum efficiency than the conventional nitride semiconductor.

As set forth above, the present invention can form the nanoscale roughened structure in the upper region of the p-capping layer via high temperature heat treatment to decrease the internal reflection thereby improving the external quantum efficiency of the nitride semiconductor.

Furthermore, the p-cladding layer obtained via high temperature growth can prevent defects existing in the surface of the active layer from being connected to the p-capping layer, thereby preventing reverse bias and electrostatic characteristics deterioration observed in conventional nitride semiconductors.

While the present invention has been shown and described in connection with the preferred embodiments, it will be apparent to those skilled in the art that modifications and variations can be made without departing from the spirit and scope of the invention as defined by the appended claims.

1. A surface treated nitride semiconductor for a light emitting diode comprising:
an n-cladding layer formed on a substrate;
an active layer having a multiple quantum well structure formed on the n-cladding layer;
a p-cladding layer formed on the active layer; and
a p-capping layer formed on the p-cladding layer in a low temperature range in which single crystal growth does not take place, the p-capping layer having a nanoscale roughened structure formed in an upper surface thereof via heat treatment in a high temperature range in which at least partial crystallization takes place.

2. The surface treated nitride semiconductor according to claim 1, wherein the p-capping layer has an amorphous or polycrystalline structure.

3. The surface treated nitride semiconductor according to claim 1, wherein the p-capping layer is formed at a temperature range from about 300 to 700° C.

4. The surface treated nitride semiconductor according to claim 1, wherein the p-capping layer is formed at a temperature range from about 300 to 400° C.

5. The surface treated nitride semiconductor according to claim 1, wherein the nanoscale roughened structure has a number of protrusions having a diameter of about 5 to 500 nm.

6. The surface treated nitride semiconductor according to claim 1, wherein the nanoscale: roughened structure has a number of pores having a width of about 5 to 500 nm.

7. The surface treated nitride semiconductor according to claim 1, wherein the nanoscale roughened structure is formed at a temperature range from about 700 to 1300° C.

8. The surface treated nitride semiconductor according to claim 1, wherein the substrate is one selected from a group consisting of a sapphire substrate, a SiC substrate, an oxide substrate and a carbide substrate.

9. A fabrication method of surface treated nitride semiconductors for a light emitting diode, the method comprising the following steps of:
(a) forming an n-cladding layer on a substrate;
(b) forming an active layer having a multiple quantum well structure on the n-cladding layer;
(c) forming a p-cladding layer on the active layer;
(d) forming a p-capping layer on the p-cladding layer at a low temperature range in which single crystal growth does not take place; and
(e) heat treating the p-capping layer at a high temperature range, whereby the p-capping layer is at least partially crystallized to form a nanoscale roughened structure in an upper region thereof.

10. The fabrication method of surface treated nitride semiconductor according to claim 9, wherein the step (d) of forming a p-capping layer is carried out at a temperature range from about 300 to 700° C.

11. The fabrication method of surface treated nitride semiconductor according to claim 9, wherein the step (d) of forming a p-capping layer is carried out at a temperature range from about 300 to 400° C.

12. The fabrication method of surface treated nitride semiconductor according to claim 9, wherein the step (d) of forming a p-capping layer is carried out at a predetermined molar ratio of III group element to V group element in the range from about 10 to 5000.

13. The fabrication method of surface treated nitride semiconductor according to claim 9, wherein the step (d) of forming a p-capping layer is carried out at a predetermined molar ratio of III group element to V group element in the range from about 10 to 1000.

14. The fabrication method of surface treated nitride semiconductor according to claim 9, wherein the heat treatment step (e) is carried out in a temperature range from about 700 to 1300° C.

15. The fabrication method of surface treated nitride semiconductor according to claim 14, wherein the heat treatment step (e) is carried out for about 1 to 10 minutes.

16. The fabrication method of surface treated nitride semiconductor according to claim 14, wherein the heat treatment step (e) is carried out for about 2 to 7 minutes.

17. The fabrication method of surface treated nitride semiconductor according to claim 9, wherein the heat treatment step (e) comprises feeding anti-decomposition gas at a flow rate in the range from about 2 to 10 liters per minute for preventing decomposition of the p-capping layer, wherein the anti-decomposition gas is at least one selected from a group consisting of ammonia (NH₃), tertiarybutylamine (N(C₄H₉)H₂), phenylhydrazine (C₆H₈N₂) and dimethylhydrazine (C₂H₈N₂).

18. The fabrication method of surface treated nitride semiconductor according to claim 17, wherein nitrgen or inactive gas is fed together with the anti-decomposition gas.

19. The fabrication method of surface treated nitride semiconductor according to claim 9, wherein the substrate is one selected from a group consisting of a sapphire substrate, a SiC substrate, an oxide substrate and a carbide substrate.
